(19) United States
(12) Patent Application Publication
(10) Pub. No.: US 2025/0323129 A1
(43) Pub. Date: Oct. 16, 2025

(54) RIGHT-HAND SEMICONDUCTOR DEVICE AND SYSTEM HAVING A RIGHT-HAND SEMICONDUCTOR DEVICE

(71) Applicant: Infineon Technologies Austria AG, Villach (AT)

(72) Inventors: Andrea Piccioni, Villach (AT); Daniel Pedone, Munchen (DE)

(21) Appl. No.: 19/091,107

(22) Filed: Mar. 26, 2025

(30) Foreign Application Priority Data
Apr. 10, 2024 (DE) 102024203250.6

(51) Int. Cl. H01L 23/495; H01L 25/07

(52) U.S. Cl. CPC H01L 23/49562; H01L 23/4951; H01L 23/4952; H01L 25/072

(57) ABSTRACT

A right-hand semiconductor device includes a control connector, a first load connector, and a second load connector, the connectors being arranged in the same plane and protruding out of a package of the semiconductor device, forming the fingers of a right-hand arrangement. The control connector is followed by the first load connector and the first load connector is followed by the second load connector. The second load connector is a thumb of the right-hand arrangement. The package includes a top side and a bottom side opposite the top side. The right-hand arrangement is seen from a topside view.

### TECHNICAL FIELD

The present disclosure relates to a right-hand semiconductor device comprising a control connector, a first load connector, and a second load connector. Further the present disclosure relates to a system comprising the right-hand semiconductor device, a corresponding left-hand semiconductor device and a connector device for connecting the left-hand semiconductor device and the right-hand semiconductor device to a Gate Driver IC.

### BACKGROUND

An active area of a e.g. Silicon Carbide (SiC) single chip is limited by the yield rate and the requirement of high-quality manufacturability. Therefore, a parallel connection of multiple chips or several discrete packages onto one common substrate is mandatory to increase a possible target output of a high-power electric converter. Discrete packages based on Silicon (Si) chips also face the same problem, however, for a different reason: a co-pack diode and the IGBT chip is capped around ˜150 A for discrete package (e.g., TO-247PLUS).

Once a designer starts to parallelize available discrete devices, e.g. Surface Mounted Devices (SMD) or Through Hole Devices (THDs), several challenges appear.

Therefore, it is an object of the present disclosure, to improve a trade-off between perfect symmetry and parasitic magnitude of a gate loop, without compromising DC+/DC− field cancellation and gate driver proper shielding.

### SUMMARY

According to a first aspect of the present disclosure, a right-hand semiconductor device is provided, comprising a control connector, a first load connector and a second load connector, wherein the connectors are arranged in the same plane and protruding out of a package of the semiconductor device, forming the fingers of a right-hand arrangement, wherein the control connector is followed by the first load connector and the first load connector is followed by the second load connector, and wherein the second load connector is a thumb of the right-hand arrangement or wherein the first load connector is followed by the second load connector and the second load connector is followed by the control connector and wherein the control connector is a thumb of the right-hand arrangement, wherein the package comprises a top side and a bottom side opposite the top side and wherein the right-hand arrangement is seen (i.e., visible) from a topside view.

According to this first aspect, a discrete package comprising a single Si/SiC chip may be provided. The package may also comprise a power transistor or multiple chips, e.g. a transistor and a diode. The transistor may have a source, a drain and gate connectors, forming a four-terminal device or a three-terminal device alternatively. In general, the four terminals are referred to as the first load connector as the source, the second load connector as the drain and the control connectors as the gate and Kelvin connectors. In the following application text, the terms control—gate, first load—source and second load—drain are used as equivalents and do not delimit the present disclosure in terms of the type of the transistor being present inside the package.

The connectors protrude out of the over molded package, so that a distal end of each of the connectors points away from the package. Typical semiconductor packages of the aforementioned kind have their connectors arranged in parallel to one another and in a common plane. Thereby the drain connector is spaced apart from the source connector for electrical clearance reasons. According to this disclosure, in case of a four terminal device, the connectors are arranged such that the gate connectors are followed by the source connector and the drain connector is arranged besides or adjacent to the source connector, however, spaced apart therefrom. In case of a three-terminal device the source connector (first load) is followed by the drain collector (second load) and the drain connector is followed by the gate connector. If the connectors of the semiconductor device were to be identified with the fingers of a human hand seen from a top perspective, the drain connector of the four terminal device or the gate connector of a three-terminal device can be identified with the thumb of a right human hand. This identification is referred to as a “right-hand arrangement”. In usual arrangements, e.g. of a standard TO-247-4 semiconductor device, the arrangement of connectors is opposite, i.e. the drain connector forms the thumb of a left-hand arrangement, i.e., can be identified with a thumb of a left human hand from a top view.

By virtue of the present first aspect of the disclosure, the above problem is at least mitigated by the provision of a mirrored package (of each of a SMD and/or THD). The gate control loop has its own parasitic inductance/capacitance/resistance. In the following this will be referred to as gate loop parasitics.

The mirrored package, if applied together with a corresponding non-mirrored package ensures symmetry with the minimum gate loop parasitic magnitude, enabling easier paralleling of power transistors paving the way for high power discrete based power converter with one single gate driver controlling multiple discrete chips.

According to an embodiment of the first aspect of the present disclosure, the bottom side is configured to be attached to a cooling structure or comprises a cooling structure. The bottom side of the package may be a side adjacent to a drain side of the transistor inside the package. The bottom side is opposite the top side which may be adjacent to a control side of the transistor inside the package. The control side of the transistor comprises a control pad (gate) and a first load pad (source) to which the respective connectors ore attached. However, to lead heat away from the transistor, a cooling structure may be attached or may be at least attachable to the bottom side of the package.

According to an embodiment of the first aspect of the disclosure, the semiconductor device comprises a single chip/die in a single package or multiple chips in a single package. It is to note that the present disclosure refers to mirrored discrete devices, which are put together on a common substrate, e.g. a Printed Circuit Board (PCB). Such device may be referred to as a discrete semiconductor device.

Examples of discrete semiconductor devices include diodes, transistors, and thyristors. Diodes are two-terminal devices that allow current to flow in only one direction and are commonly used in rectifier circuits to convert AC power to DC power. Transistors are three-terminal devices that can amplify or switch electrical signals and are used in a wide range of circuits, including amplifiers, oscillators, and digital logic circuits. Thyristors are four-layer, three-terminal semiconductor devices that are used as switches and are commonly used in power control circuits for AC loads.

According to an embodiment of the first aspect of the disclosure each of the connectors is a pin, wherein the pins are arranged in parallel. A pin may be a small, cylindrical metal component that may be used to provide an electrical connection between devices or components and may also provide a mechanical support to a device.

Pins are commonly found on the ends of cables or wires and may be inserted into corresponding sockets or connectors on a circuit board or other electronic device.

Pins may consist of a metal shaft or body, which may be coated with a layer of gold or other conductive material to improve electrical conductivity and prevent corrosion. The tip of the pin may be shaped to fit into a specific type of socket or connector, or substrate or device integrated into a multilayer substrate.

Pins allow the discrete semiconductor device(s) to be fixed onto a substrate.

Particularly, the right-hand semiconductor device comprises a Kelvin connector between the control connector and the first load connector. The Kelvin connector may be used to decouple the gate control loop from the power loop. It may provide a shorter connection that does not have to carry a high load current, and thus parasitic effects when switching the transistor may be significantly reduced.

Thereby faster switching, i.e. higher switching frequencies are possible. Faster switching may imply higher di/dt values. However, at higher di/dt values, induced voltages at parasitic stray inductances may increase in magnitude, which may lead to adverse effects in the circuit.

According to an embodiment of the first aspect of the disclosure, the semiconductor device is a through-hole-device (THD) or a Surface Mount Device (SMD).

A through-hole-device refers to an electronic component that has leads (or pins) that are inserted into through holes on a printed circuit board (PCB) or other circuit substrate and then soldered. The leads on through-hole components are usually thicker and sturdier than those on surface-mount devices, and they are often preferred for components that require a high degree of mechanical stability or that need to handle high currents or voltages.

A Surface Mount Device (SMD) is an electronic component that is designed to be mounted directly on the surface of a printed circuit board (PCB) or other circuit substrate. Unlike through-hole components, SMDs are soldered to the surface of the PCB, which allows for much smaller and more densely packed circuit boards. SMDs typically have smaller and flatter leads (or pads) than through-hole components, which allow for more efficient use of space on the board.

According to an embodiment of the first aspect of the disclosure, the right-hand semiconductor device comprises a non-monolithic leadframe, wherein the second load connector is attached to the non-monolithic leadframe via bonding wires.

The non-monolithic leadframe may also be referred to as a floating leadframe.

A non-monolithic leadframe is a type of leadframe that is used in semiconductor packaging. A leadframe is a thin metal structure that provides a means of connecting the semiconductor chip to the outside world. In contrast to a monolithic leadframe, which is made from a single piece of metal, a non-monolithic leadframe is made up of multiple pieces that are assembled together to form the leadframe structure.

Non-monolithic leadframes may be made up of a base layer, a die attach pad, and multiple lead fingers that extend out from the die attach pad. The base layer provides the mechanical support for the leadframe, while the die attach pad is used to attach the semiconductor chip to the leadframe. The lead fingers provide the electrical connections between the chip and the outside world.

Non-monolithic leadframes may be used in a variety of semiconductor packages, including quad flat no-lead (QFN) packages and small outline integrated circuit (SOIC) packages. They allow for more complex leadframe geometries and can accommodate a greater number of leads in a smaller package size.

In the present embodiment the non-monolithic leadframe may be arranged such that the drain connector which forms the thumb of the right-hand semiconductor device may be connected to a corresponding lead frame portion by bonding wires. In other words, the non-monolithic lead frame may comprise a drain portion which forms the thumb of a corresponding right-hand arrangement of the leadframe. By providing this respective portion of the leadframe, a connection between the drain portion of the leadframe and the drain connector is simplified, since the drain connector may be the same as in a usual left-hand arrangement but is connected via bonding wires to the right-hand drain portion of the floating leadframe. Hence, easy production of the mirrored semiconductor device is enabled, and costs are kept at a minimum.

According to an embodiment of the first aspect of the disclosure, the connectors are bent to enable more connection schemes.

According to a second aspect of the present disclosure a system is provided, the system comprising: the right-hand semiconductor device of the first aspect of the disclosure; a left-hand semiconductor device, comprising control connectors, a first load connector and a second load connector, wherein the connectors are arranged in the same plane and protruding out of a package of the semiconductor device, forming the fingers of a left-hand arrangement, wherein the control connectors are followed by the first load connector and the first load connector is followed by the second load connector, wherein the second load connector is a thumb of the left-hand arrangement, or wherein the first load connector is followed by the second load connector and the second load connector is followed by the control connector and wherein the control connector is a thumb of the left-hand arrangement, wherein the package comprises a top side and a bottom side opposite the top side, wherein the left-hand arrangement is seen from a topside view; and; and a connector device for connecting the left-hand semiconductor device and the right-hand semiconductor device to a Gate Driver IC.

The system according to the second aspect of the disclosure comprises the right-hand semiconductor device and a left-hand semiconductor device. Both devices may be mirroring images of one another. Both semiconductor devices are connected to a connector device.

The connector device may be a PCB or any other layered substrate, comprising at least one of a HV-layer, an interconnect layer, a gate return layer, a gate layer and a ground layer.

Both semiconductor devices may be attached in parallel to the connector device. In this arrangement the thumbs (both drain connectors) are arranged at opposite ends of the arrangement, i.e. with the remaining connectors intervening in between.

The gate connectors, however, may be spaced together, i.e. arranged neighboring to each other, and may be connected to the same gate layer in the connector device. As the gate connectors are arranged close to each other, the gate layer of the connector device may be of a reduced size. Further, as the drain connectors are spaced further apart as in an ordinary arrangement with two parallel left-hand devices, a distance from the drain connector to the gate connectors is increased. In a parallel arrangement according to the present disclosure, a drain connector of one semiconductor device may not be adjacent to the gate connector of the neighboring device. Thereby, stray inductance emerging from the drain connectors and influencing the gate current are reduced. Thereby the gate control signal is improved. The overall result is a reduction of the formfactor.

Further, in the above configuration, both the bottom side of the left-hand device and the bottom side of the right-hand device are in the same plane and may be attached to a common heat sink or cooling structure.

In one embodiment of the second aspect of the disclosure, the connector device is a layered substrate, the substrate comprising: a leadframe; a first load layer connected to the source connectors of both semiconductor devices; a control layer connected to the gate connectors of both semiconductor devices; wherein a footprint of the control layer may be smaller than a footprint of the first load layer; and wherein the control layer is arranged in a plane parallel to the plane in which the first load layer is arranged; and wherein the control layer is symmetrically arranged atop the first load layer.

As mentioned before, the control connectors are arranged close to each other. The control connectors may be connected to a common control layer, i.e. gate layer, wherein the footprint of that control layer may be smaller than a footprint of the first load layer. Hence the gate layer forms only a small island atop the first load layer, which may also be referred to as a source layer. Therefore, the size of the gate layer and the source layer can be shrinked.

Particularly, the second load connector of each semiconductor device is connected to the leadframe, wherein the leadframe is a layer which is parallel to the planes of each of the control layer and the first load layer.

In one embodiment of the second aspect of the disclosure the left-hand semiconductor device is a mirror image of the right-hand semiconductor device and wherein the left-hand semiconductor device and the right-hand semiconductor device are arranged in the same plane such that the thumb of the right-hand device and the thumb of the left-hand device do not string together. The “fingers” (i.e. the source, gate, gate return connectors) of the devices string together spacing apart the drain connectors from each other.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates a schematic layer structure of an electronic system of the prior art.

FIG. 2 illustrates a connector scheme of several semiconductor devices of the prior art.

FIG. 3 illustrates a connector scheme of several semiconductor devices according to the present disclosure.

FIG. 4a illustrates a semiconductor system of the prior art.

FIG. 4b illustrates a semiconductor system according to the present disclosure.

FIG. 5 illustrates a connector scheme of several semiconductor devices being connected to a connector device according to the prior art.

FIG. 6 illustrates a connector scheme of several semiconductor devices being connected to a connector device according to the present disclosure.

FIG. 7 shows a schematic mirrored device according to the first aspect of the disclosure.

### DETAILED DESCRIPTION

The aspects and further embodiments of the present disclosures are hereafter further described by way of examples.

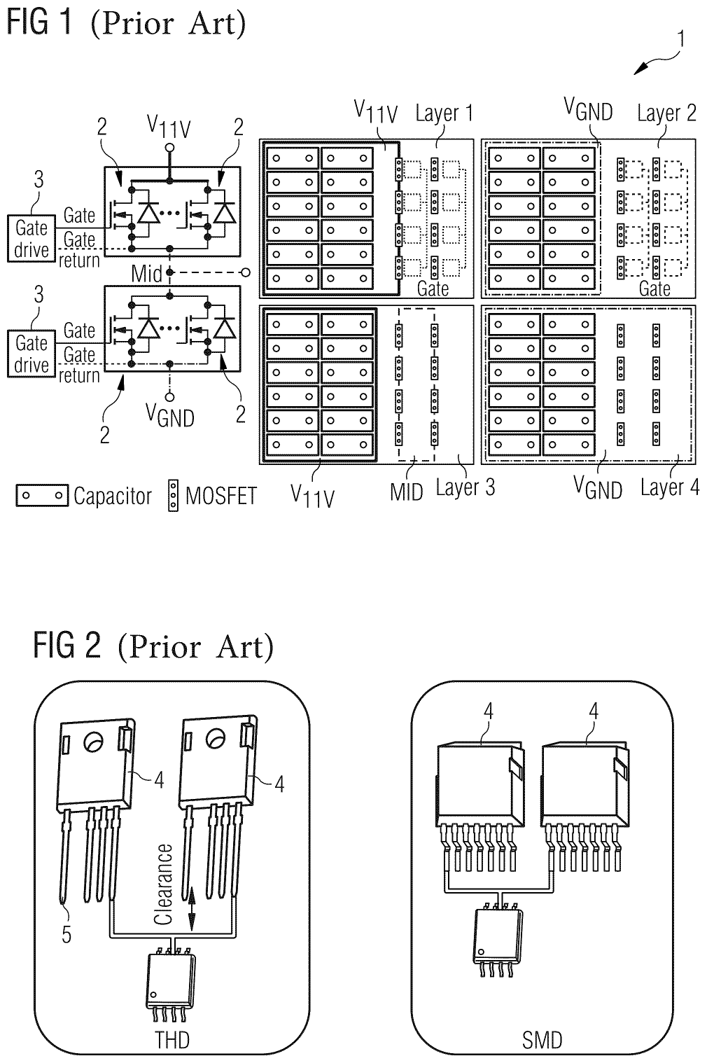

FIG. 1 shows a schematic layer structure of an electronic system 1 of the prior art. The system 1 comprises transistors 2, grouped into a high side of a half bridge and a low side of a half bridge, each side comprising at least two transistors 2. Each side is connected to a gate driver IC 3 via a gate layer (layer 1). To reduce parasitic inductances the transistors contained in the sides of the half bridge are sandwiched, symmetric and arranged between a top layer, i.e. a voltage input layer V_{HV} layer and a GND-layer. Thereby, free interconnects between the transistors (MOSFETs) and the gate driver IC 3 are paralleled and arranged symmetrically such that inductances caused by free pathlength in reduced by destructive interference. As can be seen, an elaborate layout approach is required to tackle the problem of stray inductances caused by free conductor portions.

FIG. 2 illustrates a connector scheme of several semiconductor devices of the prior art. The semiconductor devices are left-hand semiconductor devices 4. A drain connector 5 of the left-hand semiconductor device forms a thumb of the left-hand arrangement and is spaced apart from the rest of the connectors to provide proper clearance and creepage distances which are proportional to the voltage class of the system. The semiconductor device can be a SMD or a THD. In case of two THDs (e.g. the TO 247-4) being arranged in parallel, i.e. the connectors are arranged in the same plane and the devices have the same left-hand orientation. The drain connector 5 of one device is located next to the gate, gate return (Kelvin) and source connectors, which requires a certain clearance to comply with, which in turn prevents the electronic system 1 of becoming smaller.

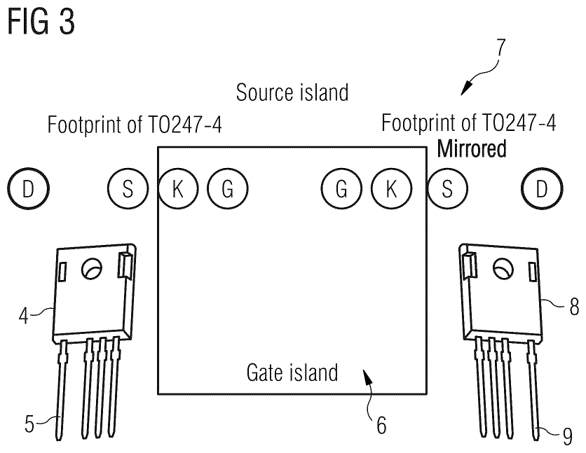

FIG. 3 illustrates a connector scheme of parallel mirrored semiconductor devices according to the present disclosure. The standard left-hand semiconductor device 4 (device in the following) is connected to a control layer 6 with its gate connector G and its gate return connector K. The source connector S is connected to a first load layer 7, which is located in a layered substrate underneath the control layer 6. A right-hand device 8, e.g. a mirrored version of a TO-247-4 package, is connected similarly to the control layer 6 and the first load layer 7. Thereby, the drain connector 9 of the right-hand device 8 is spaced apart by approximately two times the width of the devices and is not arranged in the vicinity of a neighboring non-mirrored device. This avoids inductances from the drain connectors 5,9 influencing the gate signal at the gate connectors G. The gate and gate return connectors G, K are located close to each other and can hence be connected to the same control layer 6, which may hence be smaller as in a comparable case when using non-mirrored devices. The same applies to the first load layer 7 which can be designed to have the control layer 6 on top and to overlap the control layer 6 only on the periphery, where the source connectors S of the devices 4,8 are connected to the first load layer 7.

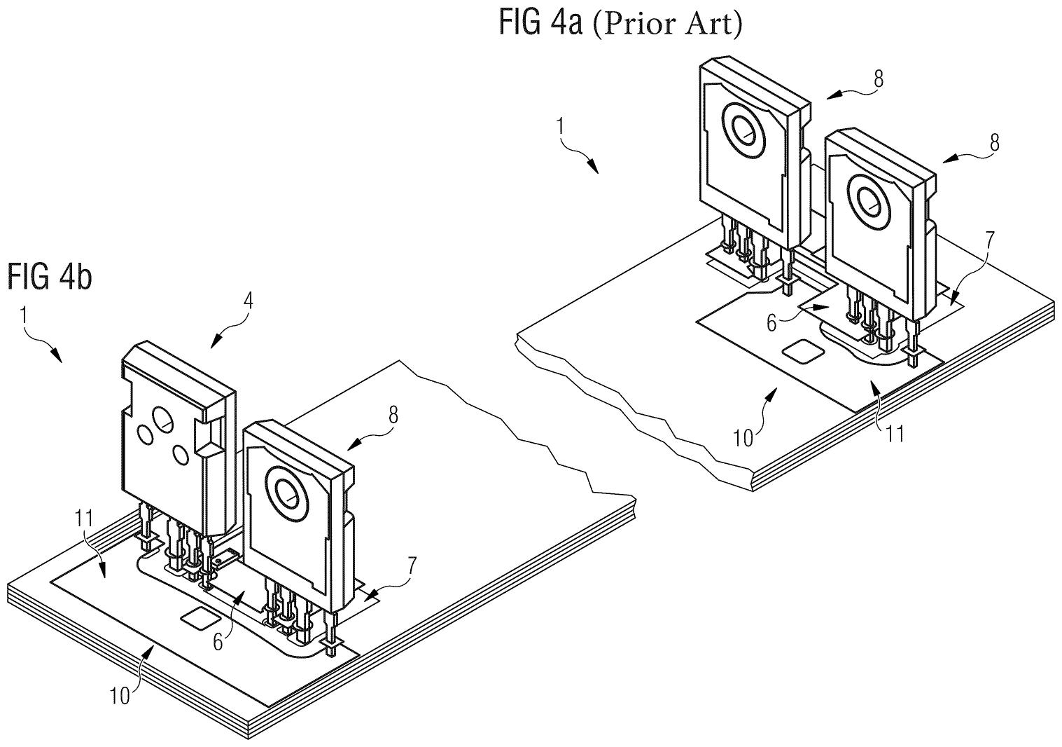

FIG. 4a illustrates a semiconductor system 1 of the prior art. The system 1 comprises two parallel arranged right-hand semiconductor devices 8. High side and low side are connected in the same orientation.

The devices 8 are connected to a connector device 10 by way of their protruding connectors. The devices 8 are pinned into the connector device 10, wherein the connectors connect to the different layers of the connector device 10. The connector device 10 comprises at least one drain layer 11, a source layer corresponding to the first load layer 7, and a gate/gate return layer corresponding to the control layer 6. In this embodiment the connectors are pins and are arranged in parallel.

FIG. 4b illustrates a semiconductor system 1. High side and low side of the devices are flipped as shown in the image. In the system 1 according to FIG. 4b, two mirrored devices 4,8, i.e. a right-hand device 8 and a left-hand device 4 are used in the same parallel arrangement as shown in FIG. 4a. The connectors of the devices 4,8 are connected to the layer structure of the connector device 10 as described above in connection with FIG. 3. However, the layer shapes and the layer structure can be different as in the usual case described in connection with FIG. 4a. and will be described in more detail below.

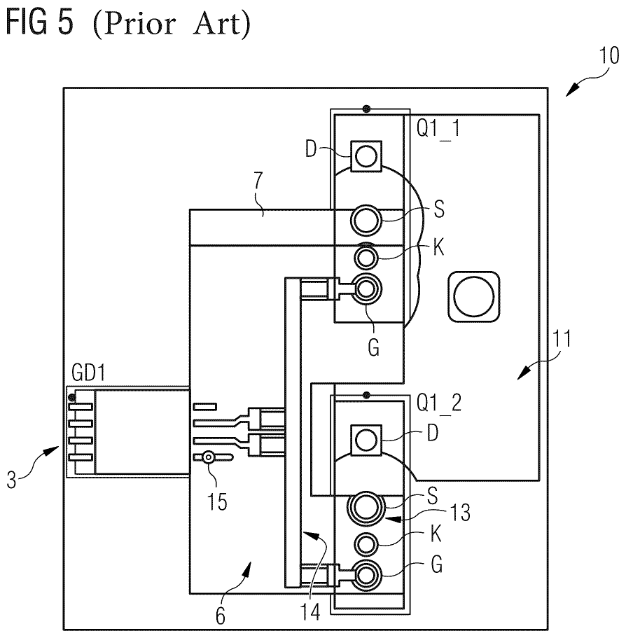

FIG. 5 illustrates a connector scheme of several semiconductor devices Q1_1 and Q1_2 being connected to a connector device 10 as shown in FIG. 4a and a respective layer structure of the connector device 10.

A substrate 12 comprises a drain layer connecting both drain connectors D of devices Q1_1 and Q1_2 (not shown) with each other. The drain layer 11 is generally U-shaped and is recessed to stay clear of the source and gate connectors S,G. Therefore, the drain layer has a plurality of circular recesses with a diameter of the respective clearance distance according to the voltage class, which is the required clearance. The source layer 7 is covered by the gate layer 6 such that the source layer 7 overlaps the gate layer 6 to enable connection of gate connector G of device Q1_1. Further, to connect the source connector S of device Q1_2 to the source layer, a bore 13 is provided in the gate layer trough which the source connector of device Q1_2 connects to the source layer without establishing electrical contact with the gate layer. Both the gate layer and the source layer comprise a recess in the vicinity of the drain connector of device Q1_2, to establish the required clearance. The gate layer is connected to the gate driver 3. The gate driver is connected to the gate areas of both Q1_1 and Q1_2 by a bus 14. A gate return terminal 15 of the gate driver Cl 3 is connected directly to the gate layer.

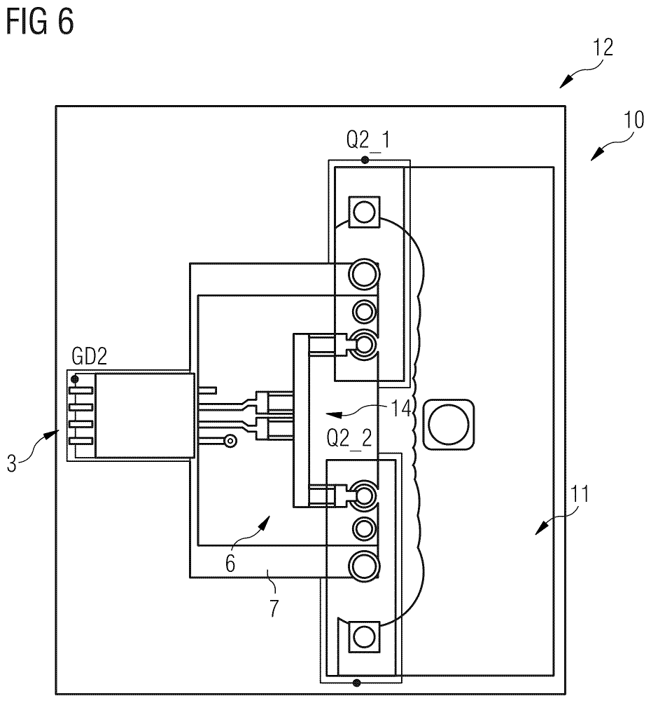

FIG. 6 illustrates a connector scheme of several semiconductor devices Q2_1 and Q2_2 being connected to a connector device 10 as shown in FIG. 4b and a respective layer structure of the connector device 10. The drain layer 11 is generally U-shaped in a lateral plane and is recessed to stay clear of the source and gate connectors S,G. In contrast to the prior art described above, the drain layer 11 encompasses both the source layer 7 and the gate layer 6. The drain layer 11 has a plurality of circular recesses with a diameter of the respective minimum clearance distance allowed according to the respective voltage class, which is the required clearance. The source layer 7 is covered by the gate layer 6, wherein the gate layer is arranged symmetrically atop the source layer. The footprint of the source layer 7 is bigger than the source footprint of the gate layer 6. The gate layer 6 does not fully overlaps the source layer 7, such that stripe-shaped areas remain clear in which the source connectors of both semiconductor devices Q2_1 and Q2_2 are connected to the source layer without the need of bores 13. As the gate connectors G of each device are arranged close to each other the bus 14 can be significantly smaller than the bus 14 of the prior art. Thereby, free conductive length is reduced, which in turn reduced loss due to parasitic stray inductances. Control layer 6 and first load layer 7 form parallel planes.

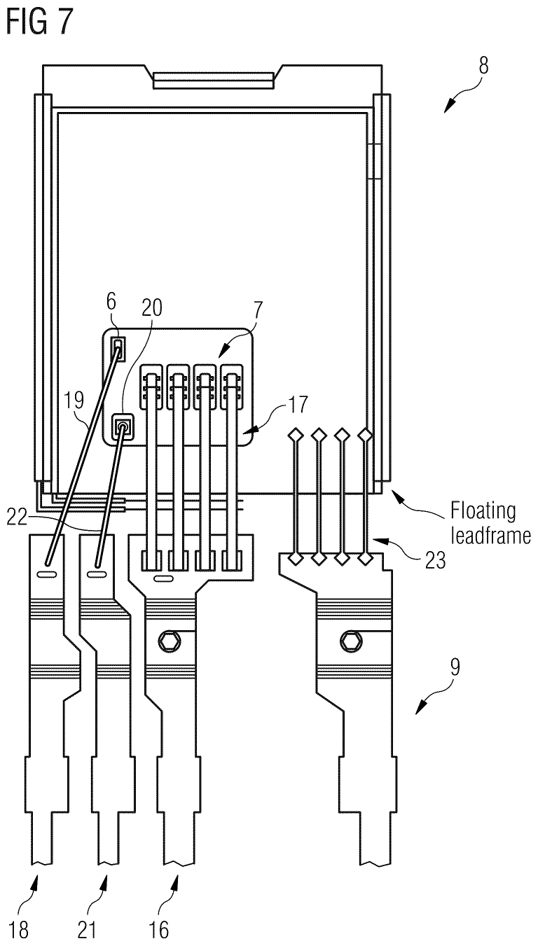

FIG. 7 shows a schematic mirrored device according to the first aspect of the disclosure, wherein the mirrored device is a right-hand device 8. The drain connector 9 forms the thumb of the right-hand device and is connected to a respective portion of the floating leadframe (not visible) inside the device 8. The leadframe is non-monolithic layer which is parallel to the planes of each of the control layer 6 and the first load layer 7. The drain connector 9 is attached to the leadframe via bonding wires 23. An array of first load layers 7 is arranged a top the device 8 to which the respective source connector 16 is connected via source interconnects 17. Further, the top side of the device 8 has a control layer 6, to which the gate connector 18 is linked via a gate interconnect 19. A gate return layer 20 is also arranged at the device 8 and connected to the gate return connector 21 by a gate return interconnect 22.

### TECHNICAL BENEFITS OF THE PRESENT DISCLOSURE

The technical benefits of the embodiments described herein can be envisaged from the below table 1. Table 1 shows a comparison of the systems shown in FIG. 4a (which is referred to by ‘A’ in table 1 below) and the claimed, mirrored embodiment of FIG. 4b (which is referred to by ‘B’ in table 1 below).

TABLE 1

| | Comparison | | | |
|---|---|---|---|---|
| | R@1 MHz-A | R@1 MHz-B | L@1 MHz -A | L@1 MHz -B |
| | (mOhm) | (mOhm) | (nH) | (nH) |
| Q1_1_D1 − | 2.405 | 2.64 | 13.73 | 15.78 |
| Out_D1 | | | | |
| Q1_2_D1 − | 2.101 | 2.66 | 13.68 | 15.98 |
| Out_D1 | | | | |
| Q1_1_S1 − | 2.46 | 2.71 | 13.42 | 12.9 |
| Out_S1 | | | | |
| Q1_2_S1 − | 3.04 | 2.73 | 13.28 | 12.88 |
| Out_S1 | | | | |
| RG1 − RG1_ON | 5.20 | 4.0 | 9.54 | 6.8 |
| RG1_2 − RG1_ON | 5.39 | 4.59 | 10.38 | 7.82 |
| RG1 − RG1_OFF | 5.46 | 4.41 | 10.18 | 7.41 |
| RG1_2 − | 5.15 | 4.22 | 9.74 | 7.17 |
| RG1_OFF | | | | |

The system of the present disclosure using two mirrored devices shows ˜30% less gate loop parasitic inductance as the system described in FIG. 4a.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the systems and devices including its preferred embodiments as outlined in the present document may be used stand-alone or in combination with the other systems and devices disclosed in this document. In addition, the features outlined in the context of a device are also applicable to a corresponding system, and vice versa.

Specifically, all of the embodiments of the present right-hand semiconductor device are applicable to the corresponding left-hand semiconductor device, which is a mirrored image of the right-hand semiconductor device.

Furthermore, all aspects of the systems and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

### LIST OF REFERENCE SIGNS

1 System
2 Transistors
3 Gate Driver IC
4 Left-hand semiconductor device
5 Drain of the left hand semiconductor device
6 Control layer
7 First load layer
8 Right-hand semiconductor device
9 Drain connector of the right-hand semiconductor device
10 Connector device
11 Drain layer
12 Substrate
13 Bore
14 Bus
15 Gate return terminal of the Gate Driver IC
16 Source connector
17 Source interconnects
18 Gate connector
19 Gate interconnect
20 Gate return layer
21 Gate return connector
22 Gate return interconnect
23 Bonding Wires

What is claimed is:

1. A right-hand semiconductor device, comprising:
a control connector;
a first load connector; and
a second load connector,
wherein the control connector, the first load connector and the second load connector are arranged in a same plane and protrude out of a package of the right-hand semiconductor device, forming a plurality of fingers of a right-hand arrangement,
wherein the control connector is followed by the first load connector and the first load connector is followed by the second load connector,
wherein:
the second load connector is a thumb of the right-hand arrangement, or
the first load connector is followed by the second load connector and the second load connector is followed by the control connector, and the control connector is the thumb of the right-hand arrangement,
wherein the package comprises a top side and a bottom side opposite the top side,
wherein the right-hand arrangement is seen from a topside view.

2. The right-hand semiconductor device of claim 1, wherein the bottom side is configured to be attached to a cooling structure or comprises a cooling structure.

3. The right-hand semiconductor device of claim 1, wherein the right-hand semiconductor device comprises a single die in a single package.

4. The right-hand semiconductor device of claim 1, wherein each of the control connector, the first load connector and the second load connector is a pin, and wherein the pins are arranged in parallel.

5. The right-hand semiconductor device of claim 1, further comprising a Kelvin connector between the control connector and the first load connector.

6. The right-hand semiconductor device of claim 1, wherein the right-hand semiconductor device is a through-hole-device or a surface mount device.

7. The right-hand semiconductor device of claim 1, further comprising a non-monolithic leadframe, wherein the second load connector is attached to the non-monolithic leadframe via bonding wires.

8. The right-hand semiconductor device of claim 1, wherein each of the control connector, the first load connector and the second load connector is bent.

9. A system, comprising:
the right-hand semiconductor device of claim 1; and
a left-hand semiconductor device comprising a control connector, a first load connector, and a second load connector, wherein the control connector, the first load connector and the second load connector of the left-hand semiconductor device are arranged in a same plane and protrude out of a package of the left-hand semiconductor device, forming a plurality of fingers of a left-hand arrangement, wherein the control connector of the left-hand semiconductor device is followed by the first load connector of the left-hand semiconductor device, the first load connector of the left-hand semiconductor device is followed by the second load connector of the left-hand semiconductor device, and the second load connector of the left-hand semiconductor device is a thumb of the left-hand arrangement, or the first load connector of the left-hand semiconductor device is followed by the second load connector of the left-hand semiconductor device, the second load connector of the left-hand semiconductor device is followed by the control connector of the left-hand semiconductor device, and the control connector of the left-hand semiconductor device is the thumb of the left-hand arrangement, wherein the package of the left-hand semiconductor device comprises a top side and a bottom side opposite the top side, wherein the left-hand arrangement is seen from a topside view; and
a connector device configured to connect the left-hand semiconductor device and the right-hand semiconductor device to a gate driver integrated circuit (IC).

10. The system of claim 9, wherein the connector device is a layered substrate, wherein the layered substrate comprises:
a leadframe;
a first load layer connected to the first load connectors of both semiconductor devices; and
a control layer connected to the control connectors of both semiconductor devices,
wherein a footprint of the control layer is smaller than a footprint of the first load layer,
wherein the control layer is arranged in a plane parallel to the plane in which the first load layer is arranged, and
wherein the control layer is symmetrically arranged atop the first load layer.

11. The system of claim 10, wherein the second load connector of each semiconductor device is connected to the leadframe, and wherein the leadframe is a layer which is parallel to the planes of each of the control layer and the first load layer.

12. The system of claim 9, wherein the left-hand semiconductor device is a mirror image of the right-hand semiconductor device, and wherein the left-hand semiconductor device and the right-hand semiconductor device are arranged in the same plane such that the thumb of the right-hand device and the thumb of the left-hand device do not string together.
